(19) United States
(12) Patent Application Publication
(10) Pub. No.: US 2024/0355967 A1
(43) Pub. Date: Oct. 24, 2024

(54) Light Emission Device And Method Of Forming The Same

(71) Applicant: Nanyang Technological University, Singapore (SG)

(72) Inventors: Donguk NAM, Singapore (SG); Daniel BURT, Singapore (SG); Yongduck JUNG, Singapore (SG); Youngmin KIM, Singapore (SG); Hyo Jun JOO, Singapore (SG)

(73) Assignee: Nanyang Technological University, Singapore (SG)

(21) Appl. No.: 18/625,406

(22) Filed: Apr. 3, 2024

(30) Foreign Application Priority Data
Apr. 21, 2023 (SG) 10202301118T

(51) Int. Cl. H01L 33/28; H01L 33/00; H01L 33/10

(52) U.S. Cl. CPC H01L 33/285; H01L 33/0083; H01L 33/10

(57) ABSTRACT

Various embodiments may provide a light emission device including a stacked arrangement having a first pad region, a second pad region and a bridge region. At least a portion of the first pad region may include a portion of a first doped layer, while at least a portion of the second pad region may include a further portion of the first doped layer, a portion of a second doped layer, and a portion of an intrinsic layer. A percentage concentration of tin (Sn) of the intrinsic layer may be higher than that of the first doped layer, and that of the second doped layer. The light emission device may include a first tensile stressed metal pad in contact with the portion of the first doped layer, and a second tensile stressed metal pad in contact with the portion of the second doped layer.

### CROSS-REFERENCE TO RELATED APPLICATION

This application claims the benefit of priority of Singapore application No. 10202301118T filed Apr. 21, 2023, the contents of it being hereby incorporated by reference in its entirety for all purposes.

### TECHNICAL FIELD

Various embodiments of this disclosure may relate to a light emission device. Various embodiments of this disclosure may relate to a method of forming a light emission device.

### BACKGROUND

The ability to have an electrically pumped low-threshold laser on silicon (Si) promises to enable a range of exciting technologies, from ultra-compact, low-cost Light Detection and Ranging (LiDAR) chips to ultra-fast optical interconnects for data centers. For this reason, the realization of a Si compatible laser diode is often referred to as the ‘holy grail’ of Si photonics, owing to its unique potential in unlocking the full power of photonic-integrated circuits. However, Si compatible materials are naturally poor emitters of light due to their indirect bandgap nature, which has prevented any practical realization of an on-chip Si compatible laser.

### SUMMARY

Various embodiments may provide a light emission device. The light emission device may include a substrate. The light emission device may also include a stacked arrangement over the substrate, the stacked arrangement having a first pad region, a second pad region and a bridge region extending between the first pad region and the second pad region, the bridge region having a lateral width smaller than a lateral width of the first pad region, and smaller than a lateral width of the second pad region. At least a portion of the first pad region may include a portion of a first doped layer. At least a portion of the second pad region may include a further portion of the first doped layer, a portion of a second doped layer, and a portion of an intrinsic layer, the portion of the intrinsic layer between the further portion of the first doped layer and the portion of the second doped layer. The first doped layer may include germanium (Ge) or germanium-tin (GeSn), and may be of a first electrical conductivity type. The second doped layer may include germanium (Ge) or germanium-tin (GeSn), and may be of a second electrical conductivity type different from the first electrical conductivity type. The intrinsic layer may include germanium-tin (GeSn), such that a percentage concentration of tin (Sn) of the intrinsic layer is higher than a percentage concentration of tin (Sn) of the first doped layer, and is higher than a percentage concentration of tin (Sn) of the second doped layer. The light emission device may additionally include a first tensile stressed metal pad in contact with the portion of the first doped layer. The light emission device may also include a second tensile stressed metal pad in contact with the portion of the second doped layer, such that first tensile-stressed metal pad and the second tensile-stressed metal pad cause a tensile strain in the bridge region.

Various embodiments may relate to a method of forming a light emission device. The method may include forming a stacked arrangement over a substrate, the stacked arrangement having a first pad region, a second pad region and a bridge region extending between the first pad region and the second pad region, the bridge region having a lateral width smaller than a lateral width of the first pad region, and smaller than a lateral width of the second pad region. At least a portion of the first pad region may include a portion of a first doped layer. At least a portion of the second pad region may include a further portion of the first doped layer, a portion of a second doped layer, and a portion of an intrinsic layer, the portion of the intrinsic layer between the further portion of the first doped layer and the portion of the second doped layer. The first doped layer may include germanium (Ge) or germanium-tin (GeSn), and may be of a first electrical conductivity type. The second doped layer may include germanium (Ge) or germanium-tin (GeSn), and may be of a second electrical conductivity type different from the first electrical conductivity type. The intrinsic layer may include germanium-tin (GeSn), such that a percentage concentration of tin (Sn) of the intrinsic layer is higher than a percentage concentration of tin (Sn) of the first doped layer, and is higher than a percentage concentration of tin (Sn) of the second doped layer. Forming the light emission device may also include forming a first tensile stressed metal pad in contact with the portion of the first doped layer. Forming the light emission device may further include forming a second tensile stressed metal pad in contact with the portion of the second doped layer, such that first tensile-stressed metal pad and the second tensile-stressed metal pad cause a tensile strain in the bridge region.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows a general illustration of a light emission device according to various embodiments.

FIG. 2 shows a general illustration of a method of forming a light emission device according to various embodiments.

FIG. 3 shows a table comparing a device according to various embodiments with the state-of-the art devices.

FIG. 4 shows (a) a microscopy image of the fabricated device according to various embodiments with a 2.0% uniaxial tensile strained nanowire with two mirrors on either side to confine the light and (b) simulation result using finite element modelling (FEM) showing the excellent homogeneity of the strain within the nanowire according to various embodiments.

FIG. 5 shows (a) a schematic of a GeSn on insulator (GeSnOI) structure according to various embodiments; (b) a schematic of a GeSn on dual insulator (GeSnODI) structure according to various embodiments; and (c) a cross-sectional transmission microscopy (TEM) of the successfully bonded GeSnODI structure according to various embodiments.

FIG. 6 shows a schematic of a laser diode or structure according to various embodiments.

FIG. 7A shows a scanning electron microscope (SEM) image of a fabricated light emitting diode (LED) according to various embodiments.

FIG. 7B shows a plot of current (in Amperes or A) as a function of voltage (in volts or V) illustrating the measured current-voltage (I-V) characteristics of the fabricated light emitting diode (LED) according to various embodiments.

FIG. 8A shows a schematic of the formation of the stacked arrangement over the substrate according to various embodiments.

FIG. 8B shows a plot of q_{z} (in per nanometer or nm⁻¹) as a function of qₓ (in per nanometer or nm⁻¹) illustrating the reciprocal space mapping (RSM) measurement around the asymmetrical (224) X-Ray diffraction (XRD) reflection peak indicating the tin (Sn) content and strain in the stacked arrangement according to various embodiments.

FIG. 8C shows a scanning electron microscopy (SEM) image depicting the fabricated light emitting diode according to various embodiments.

FIG. 9A shows a plot of current (in milli-Amperes or mA) as a function of bias (in volts or V) illustrating the current-voltage (I-V) measurements for two light emitting diodes (D1 and D2) according to various embodiments with forward and reverse bias operations.

FIG. 9B shows a plot of electroluminescence EL (in arbitrary units or a.u.) as a function of wavelength (in micrometers or μm) illustrating the variation at different drive currents provided to the emission device at room temperature according to various embodiments.

FIG. 9C shows a plot of integrated intensity (in arbitrary units or a.u.)/peak position (in micrometers or μm) as a function of drive current (in milli-Amperes or mA) illustrating the variation of integrated intensity and peak position with drive current provided to the emission device according to various embodiments.

FIG. 9D shows a plot of electroluminescence EL (in arbitrary units or a.u.) as a function of wavelength (in micrometers or μm) illustrating the variation at different drive currents provided to the emission device at 80 Kelvins (K) according to various embodiments.

FIG. 9E shows a table comparing the light emitting diode according to various embodiments with different prior devices.

FIG. 10 shows simulation of the thermal dissipation and optical confinement for the microbridge light emitting diodes according to various embodiments in three cases: (a) unreleased structure without under etch of the germanium virtual substrate (Ge VS) layer; (b) suspended structure with the germanium virtual substrate (Ge VS) layer under-etched; and (c) complete under etch of the germanium virtual substrate (Ge VS) layer to fully release the stacked arrangement, and arrangement on a silicon dioxide (SiO₂) substrate.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the light emission devices are analogously valid for the other light emission devices. Similarly, embodiments described in the context of a method are analogously valid for a light emission device, and vice versa.

In recent years, there has been extensive interest in converting one of the Si compatible materials, germanium (Ge), into a direct bandgap material, to realize such an on-chip laser. Two approaches are conventionally utilized to transform Ge into an efficient light emitter: tensile strain engineering and tin (Sn) alloying. Recently, an exciting hybrid approach combining tensile strain engineering and germanium tin (GeSn) alloys have shown the best lasing characteristics with ultra-low lasing thresholds. The crucial next step towards the realization of a practical on-chip laser is to add the last major functionality via electrical injection.

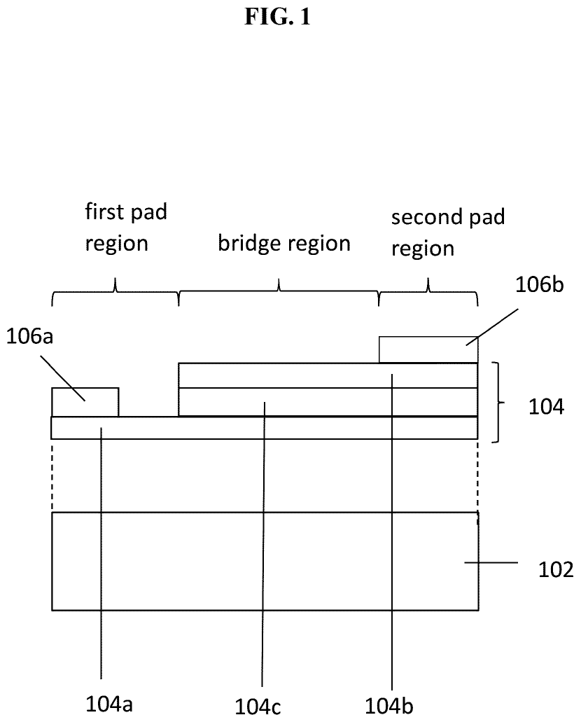

FIG. 1 shows a general illustration of a light emission device according to various embodiments. The light emission device may include a substrate 102. The light emission device may also include a stacked arrangement 104 over the substrate 102, the stacked arrangement 104 having a first pad region, a second pad region and a bridge region extending between the first pad region and the second pad region, the bridge region having a lateral width smaller than a lateral width of the first pad region, and smaller than a lateral width of the second pad region. At least a portion of the first pad region may include a portion of a first doped layer 104a. At least a portion of the second pad region may include a further portion of the first doped layer 104a, a portion of a second doped layer 104b, and a portion of an intrinsic layer 104c, the portion of the intrinsic layer 104c between the further portion of the first doped layer 104a and the portion of the second doped layer 104b. The first doped layer 104a may include germanium (Ge) or germanium-tin (GeSn), and may be of a first electrical conductivity type. The second doped layer 104b may include germanium (Ge) or germanium-tin (GeSn), and may be of a second electrical conductivity type different from the first electrical conductivity type. The intrinsic layer 104c may include germanium-tin (GeSn), such that a percentage concentration of tin (Sn) of the intrinsic layer 104c is higher than a percentage concentration of tin (Sn) of the first doped layer 104a, and is higher than a percentage concentration of tin (Sn) of the second doped layer 104c. The light emission device may additionally include a first tensile stressed metal pad 106a in contact with the portion of the first doped layer 104a. The light emission device may also include a second tensile stressed metal pad 106b in contact with the portion of the second doped layer 104b, such that first tensile-stressed metal pad 106a and the second tensile-stressed metal pad 106b cause a tensile strain in the bridge region.

In other words, various embodiments may relate to a light emission device with a stacked arrangement 104. The stacked arrangement 104 may include three layers, with the middle layer 104c being a GeSn layer having a concentration of tin (Sn) higher than the other two layers 104a, 104b. The light emission device may also include metal pads 106a, 106b configured to cause a tensile strain in a bridge region of the light emission device. The layer 104a may be of a first electrical conductivity type, while the second layer 104b may be of a first electrical conductivity type.

For avoidance of doubt, FIG. 1 is intended to illustrate some features of the device according to various embodiments, and is not intended to limit, for instance, the shape, dimensions, size, orientation etc. of the various features.

In various embodiments, the light emission device may be configured to emit light upon application of a potential difference between the first tensile stressed metal pad 106a and the second tensile stressed metal pad 106b.

In various embodiments, at least a portion of the bridge region may include an additional portion of the first doped layer 104a, a further portion of the second doped layer 104b and a further portion of the intrinsic layer 104c. The further portion of the intrinsic layer 104c may be between the additional portion of the first doped layer 104a and the further portion of the second doped layer 104b.

In various embodiments, the light emission device may also include one or more buffer layers between the substrate 102 and the stacked arrangement 104. In various embodiments, the one or more buffer layers may include a first buffer layer including silicon dioxide (SiO₂) and/or aluminum nitride (AlN). The one or more buffer layers may further include a second buffer layer on the first buffer layer, the second buffer layer including aluminum oxide (Al₂O₃) or silicon dioxide (SiO₂). In various embodiments, a portion of the second buffer layer under the bridge region may be removed, and the bridge region (e.g. the additional portion of the first doped layer 104a) may be in contact with the first buffer layer. Contacting the bridge region with the first buffer layer may help improve thermal management.

In various other embodiments, the one or more buffer layers may include a virtual substrate (VS) layer including germanium (Ge). The one or more buffer layers may further include a first buffer layer on the virtual substrate layer, the first buffer layer including germanium-tin (GeSn). The one or more buffer layers may further include a second buffer layer on the first buffer layer, the second buffer layer also including germanium-tin (GeSn). A percentage concentration of tin (Sn) of the second buffer layer may be higher than a percentage concentration of tin (Sn) of the first buffer layer.

In various embodiments, the bridge region may be over a gap between the first buffer layer and the substrate 102. The gap may result from the under-etching of a portion of the virtual substrate layer.

In various other embodiments, the bridge region may be in contact with the substrate 102. A portion of the first buffer layer and a portion of the second buffer layer under the bridge region may also be removed (in addition to the under-etching of the portion of the virtual substrate layer). The additional portion of the first doped layer 104a in the bridge region may be in contact with the substrate 102, due to bridge region (of the stacked arrangement) being directly laid on the substrate 102 after under-etching of the portion of the virtual substrate layer, the portion of the first buffer layer and the portion of the second buffer layer.

In various embodiments, a metal pad having residual stress, such as the first tensile stressed metal pad 106a or the second tensile stressed metal pad 106b, may be due to the mismatch in a thermal expansion coefficient of the metal pad and a thermal expansion coefficient of the underlying layer. For instance, the first metal pad 106a may be tensile stressed due to a mismatch in a thermal expansion coefficient of the first metal pad 106a and a thermal expansion coefficient of the first doped layer 104a under and in contact with the first metal pad 106a. The second metal pad 106b may be tensile stressed due to a mismatch in a thermal expansion coefficient of the second metal pad 106b and a thermal expansion coefficient of the second doped layer 104b under and in contact with the second metal pad 106b. The metal of the metal pad may initially be deposited at a higher temperature (e.g. exceeding room temperature), followed by a gradual cooling to a lower temperature (e.g. room temperature). This process may induce residual stress in the metal pad due to the thermal expansion coefficient mismatch between the metal and its underlying layer. Furthermore, the level of stress in the metal may be varied or customized by adjusting factors such as the deposition temperature, the composition of the metal, or the thickness of the metal pad.

The first tensile stressed metal pad 106a and the second tensile stressed metal pad 106b may also serve to allow for electrical pumping of the light emission device.

In various embodiments, the first tensile stressed metal pad 106a and/or the second tensile stressed metal pad 106b may include any suitable metal, providing that the coefficient of thermal expansion of the metal pad and the coefficient of thermal expansion of the underlying layer are taken into account. The first tensile stressed metal pad 106a may include any suitable metal having a thermal expansion coefficient higher than a thermal expansion coefficient of the underlying first doped layer 104a. The second tensile stressed metal pad 106a may include any suitable metal having a thermal expansion coefficient higher than a thermal expansion coefficient of the underlying second doped layer 104b. For instance, the first tensile stressed metal pad may include gold and/or chromium, and the second tensile stressed metal pad may also include gold and/or chromium.

In various embodiments, the first pad region may include a first reflector. The second pad region may include a second reflector. The first reflector may be a distributed Bragg reflector or a corner cube mirror. The second reflector may be a distributed Bragg reflector or a corner cube mirror.

In various embodiments, the first electrical conductivity type may be p-doped, while the second electrical conductivity type may be n-doped. In various other embodiments, the first electrical conductivity type may be n-doped (or p-type), while the second electrical conductivity type may be p-doped (or n-type). A Ge or GeSn layer may be n-doped by introducing dopants such as phosphorus (P), arsenic (As) or antimony (Sb). A Ge or GeSn layer may be p-doped by introducing dopants such as boron (B), gallium (Ga) or indium (In). In various embodiments, the light emission device may be a laser diode. In various other embodiments, the light emission device may be a light emitting diode (LED).

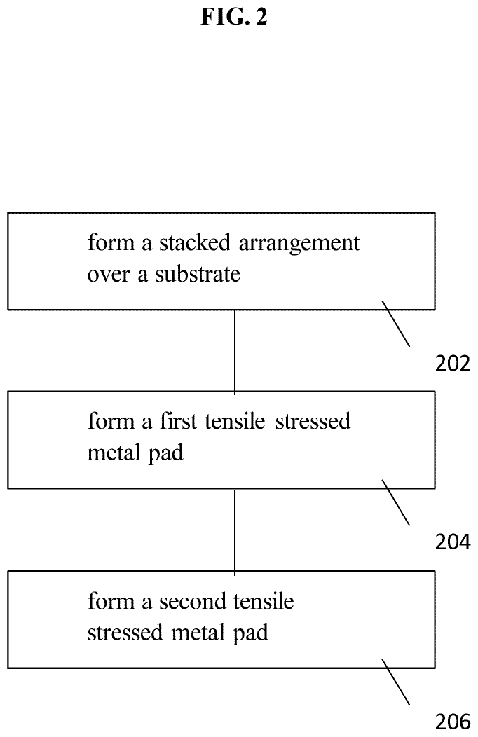

FIG. 2 shows a general illustration of a method of forming a light emission device according to various embodiments. The method may include, in 202, forming a stacked arrangement over a substrate, the stacked arrangement having a first pad region, a second pad region and a bridge region extending between the first pad region and the second pad region, the bridge region having a lateral width smaller than a lateral width of the first pad region, and smaller than a lateral width of the second pad region. At least a portion of the first pad region may include a portion of a first doped layer. At least a portion of the second pad region may include a further portion of the first doped layer, a portion of a second doped layer, and a portion of an intrinsic layer, the portion of the intrinsic layer between the further portion of the first doped layer and the portion of the second doped layer. The first doped layer may include germanium (Ge) or germanium-tin (GeSn), and may be of a first electrical conductivity type. The second doped layer may include germanium (Ge) or germanium-tin (GeSn), and may be of a second electrical conductivity type different from the first electrical conductivity type. The intrinsic layer may include germanium-tin (GeSn), such that a percentage concentration of tin (Sn) of the intrinsic layer is higher than a percentage concentration of tin (Sn) of the first doped layer, and is higher than a percentage concentration of tin (Sn) of the second doped layer. Forming the light emission device may also include, in 204, forming a first tensile stressed metal pad in contact with the portion of the first doped layer. Forming the light emission device may further include, in 206, forming a second tensile stressed metal pad in contact with the portion of the second doped layer, such that first tensile-stressed metal pad and the second tensile-stressed metal pad cause a tensile strain in the bridge region.

In other words, the method may include forming the stacked arrangement as well as the first tensile stressed metal pad and the second tensile stressed metal pad.

For avoidance of doubt, FIG. 2 is not intended to limit the sequence of the various steps. For instance, step 204 may occur before, after, or at the same time as step 206. In various embodiments, step 204 and step 206 may occur after step 202.

In various embodiments, at least a portion of the bridge region may include an additional portion of the first doped layer, a further portion of the second doped layer and a further portion of the intrinsic layer. The further portion of the intrinsic layer may be between the additional portion of the first doped layer and the further portion of the second doped layer.

In various embodiments, the portion of the first pad region including the portion of the first doped layer is formed by etching an overlying portion of the second doped layer and an overlying portion of the intrinsic layer.

In various embodiments, the method may include forming one or more buffer layers between the substrate and the stacked arrangement. In various embodiments, the one or more buffer layers may be formed before forming the stacked arrangement.

In various embodiments, the one or more buffer layer may include a first buffer layer including silicon dioxide (SiO₂) and/or aluminum nitride (AlN). The one or more buffer layers may further include a second buffer layer on the first buffer layer, the second buffer layer including aluminum oxide (Al₂O₃) or silicon dioxide (SiO₂).

In various other embodiments, the one or more buffer layers may include a virtual substrate (VS) layer including germanium. The one or more buffer layers may further include a first buffer layer on the virtual substrate layer, the first buffer layer including germanium-tin (GeSn). The one or more buffer layers may further include a second buffer layer on the first buffer layer, the second buffer layer also including germanium-tin (GeSn).

In various embodiments, the method may include under etching a portion of the virtual substrate layer between a portion of the first buffer layer and the substrate to form a gap under the bridge region of the stacked arrangement, or further under etching a portion of the first buffer layer and the portion of the second buffer layer under the bridge region to allow the bridge region to be in contact with the substrate.

In other words, in various embodiments, the bridge region may be over a gap between the first buffer layer and the substrate due to under etching of the portion of the virtual substrate layer. In various other embodiments, the method may include further under etching a portion of the first buffer layer and a portion of the second buffer layer under the bridge region, and directly laying the bridge region (of the stacked arrangement) on the substrate (such that the additional portion of the first doped layer in the bridge region is in contact with the substrate) after under etching the portion of the virtual substrate layer, the portion of the first buffer layer and the portion of the second buffer layer.

In various embodiments, the method may include forming a first reflector in the first pad region. The method may also include forming a second reflector in the second pad region.

In various embodiments, the first reflector may be a distributed Bragg reflector or a corner cube mirror. The second reflector may be a distributed Bragg reflector or a corner cube mirror.

In various embodiments, forming the first tensile stressed metal pad and/or the second tensile stressed metal may include depositing a suitable metal under a first temperature on a layer (e.g. first doped layer for the first tensile stressed metal pad, second doped layer for the second tensile stressed metal pad), and allowing the deposited metal to cool to a second temperature lower than the first temperature. Due to the mismatch of the thermal expansion coefficients between the metal and the underlying layer, the resulting metal pad formed may be tensile stressed. The level of stress in the metal may be varied or customized by adjusting factors such as the deposition temperature, the composition of the metal, or the thickness of the metal pad.

### Design 1

Various embodiments may provide aspects required for an efficient and Si-compatible on-chip emission device or laser. Various embodiments may have a unique stressed electrode design that provides key dual functionalities such as electrical pumping and tensile strain engineering. Various embodiments may have a highly strained and uniform GeSn gain medium with high material quality. Various embodiments may have an excellent optical cavity which does not interfere with the strain field. Various embodiments may have superior thermal management by employing unique dual-insulator layers.

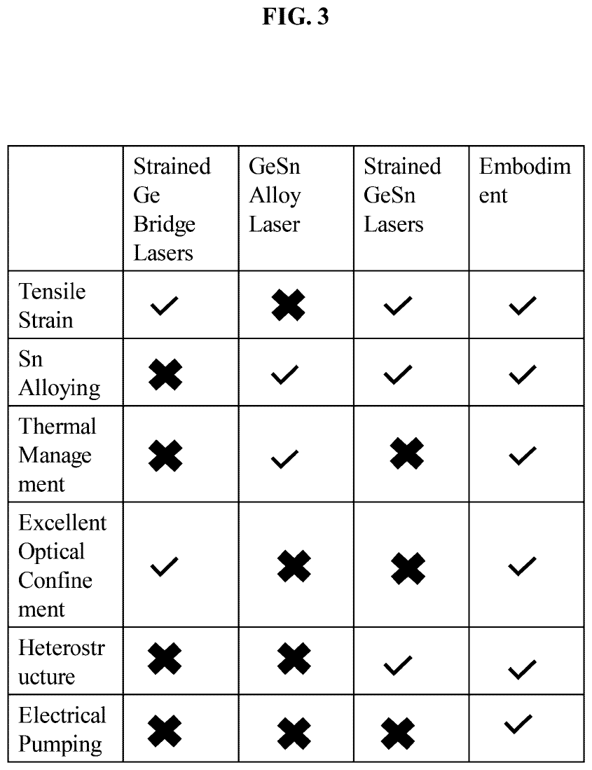

The stressed electrode laser structure may offer numerous advantages over the current state-of-the-art technology. As metal stressors introduce the tensile strain, the laser structure may naturally be optimized for electrical pumping, which may be a strict requirement for a practical device. Stressed electrodes may currently provide the only route towards electrically pumped strained GeSn lasers, which in turn may be the most promising route towards a practical on-chip laser. Additionally, by using the GeSn on dual insulator (GeSnODI) material platform according to various embodiments, the thermal management and optical confinement may be drastically improved compared to other structures which place the GeSn in contact with air or Si. This superior thermal management may allow for room temperature and continuous-wave operation of the laser structure, another strict requirement for a practical device that no other technology currently satisfies. The stressed electrodes and GeSnODI may be combined with the fact that the entire fabrication procedure is fully compatible with the industry-standard complementary metal-oxide-semiconductor (CMOS) process. In view of the abovementioned, various embodiments may be currently the most viable candidate for a market-ready laser. FIG. 3 shows a table comparing a device according to various embodiments with the state-of-the art devices.

Conventional tensile strain engineering on suspended bridge structures relies on the fact that Ge grown on Si has an initially tensile strain. By releasing two tensile strained Ge pads (achieved by etching away the layer underneath Ge), an enhanced tensile strain is imparted into the narrow bridge.

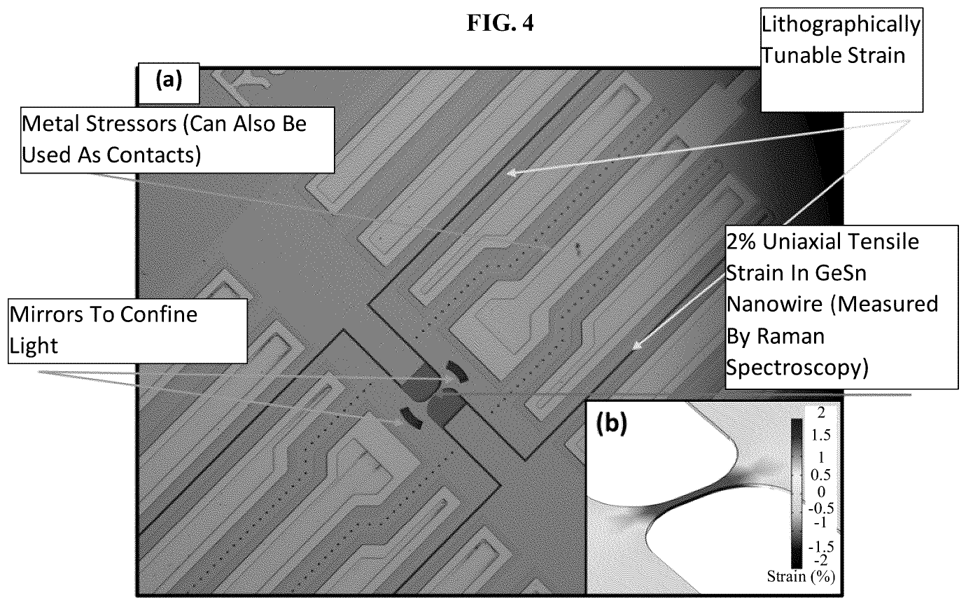

However, in the case of GeSn, which is grown on Si using a Ge buffer layer, the GeSn layer has an initially compressive strain. Therefore, the previously described method would only introduce enhanced compressive strain, which may in turn harm the lasing. To overcome this issue, the laser structure according to various embodiments may use tensile-stressed metal pads deposited onto the partially etched GeSn pad region, which after subsequent releasing, impart a tensile strain into the GeSn nanowire bridges, despite the initial compressive strain in GeSn. FIG. 4 shows (a) a microscopy image of the fabricated device according to various embodiments with a 2.0% uniaxial tensile strained nanowire with two mirrors on either side to confine the light and (b) simulation result using finite element modelling (FEM) showing the excellent homogeneity of the strain within the nanowire according to various embodiments. Two reflectors or mirrors can be seen on both sides of the nanowire to trap the light. The metal stressors can be seen on both sides of the nanowire and reflectors or mirrors as long strips. These metal stressors may be lithographically tuned to alter the strain. The metal stressors, when released may pull on the nanowire to impart the tensile strain. The amount of tensile strain may be controlled by changing the design (lithographically). FIG. 4(b) shows a three-dimensional (3D) finite element modelling (FEM) simulation of the tensile strain in the nanowire. The strain is extremely homogenous in all three dimensions.

Both uniaxial and biaxial strain can be introduced by merely altering the geometry of the pads and bridge, making the strain engineering platform extremely versatile. By combining a relatively low Sn-content GeSn with high tensile strain, a much higher material quality may be achieved (relative to high-Sn content layers which introduce many defects). Additionally, a direct bandgap configuration can be achieved, resulting in an excellent gain medium for lasing.

An optical cavity may be introduced by placing Distributed Bragg Reflectors (DBRs) or corner cube mirrors in the pad regions still containing GeSn. Photons resonate between these mirrors which exhibit a large degree of optical confinement, resulting in stimulated emission and lasing. After releasing the GeSn bridge and stressed metal pads, the entire device may be brought into contact with the underlying insulator layers (SiO₂/AlN), thereby resulting in superior thermal management whilst maintaining excellent optical confinement. The metal pads can have etching holes to facilitate faster release and higher tensile strain by reducing the distance of release.

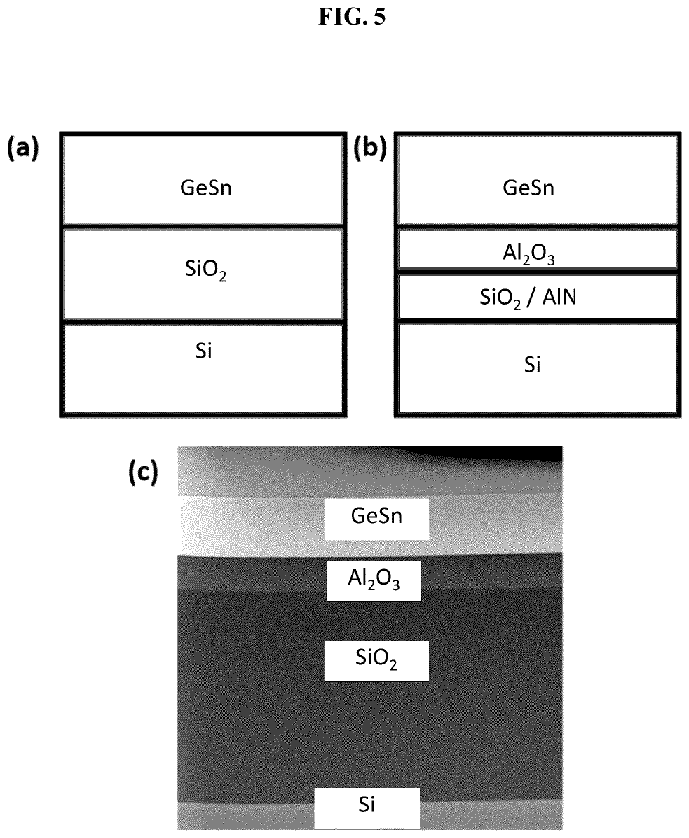

The GeSn on dual insulator (GeSnODI) material platform or structure may be created using low-temperature wafer bonding techniques. By using two buffer or insulator layers, the buffer or insulator layer underneath the GeSn can be selectively removed, and the GeSn can subsequently be brought into contact with the other buffer or insulator layer. Various embodiments may therefore offer drastic improvements in thermal management compared to the conventional method of suspending the GeSn in the air, due to enhanced thermal conduction paths into the Si substrate. FIG. 5 shows (a) a schematic of a GeSn on insulator (GeSnOI) structure (including a single layer of silicon dioxide) according to various embodiments; (b) a schematic of a GeSn on dual insulator (GeSnODI) structure according to various embodiments; and (c) a cross-sectional transmission microscopy (TEM) of the successfully bonded GeSnODI structure according to various embodiments. The improved thermal management may mean that optical losses are kept extremely low, which in turn enables continuous-wave and room temperature operation, both of which are necessary for a practical device.

The GeSnODI may utilize silicon dioxide and/or aluminum nitride (SiO₂/AlN) as the first buffer or insulation layer, and aluminum oxide (Al₂O₃) or silicon dioxide (SiO₂) as the second buffer or insulation layer on the first buffer or insulation layer. The AlN may have a thermal conductivity that is two orders of magnitude higher than SiO₂, resulting in superior thermal management. Furthermore, AlN has only a slightly higher refractive index of 1.8 at the target lasing wavelengths, still offering excellent optical confinement.

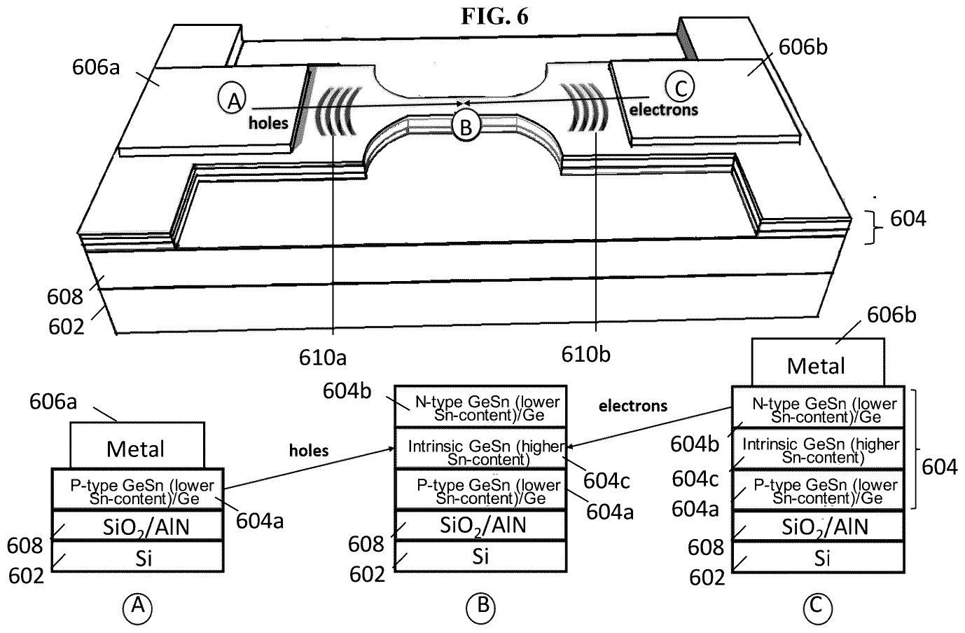

Both optically pumped lasers and electrically pumped lasers may be created using this method. Not only do the metal pads apply the tensile strain to the nanowire, the metal pads can also simultaneously inject electrical current into the active gain medium. FIG. 6 shows a schematic of a laser diode or structure according to various embodiments. FIG. 6 also illustrates how electrical pumping is achieved in the laser diode or structure. The electrically pumped laser diode or structure can be realized by using a vertical stacked arrangement 604 (alternatively referred to as p-type-intrinsic-n-type (PIN) heterojunction or stack) as the active gain medium. As shown in FIG. 6, the laser structure or diode may include a substrate 602, the stacked arrangement 604 over the substrate 602, as well as tensile stressed metal pads 606a, 606b over the stacked arrangement 604. The laser structure or diode may further include a SiO₂/AlN layer 608 between the substrate 602 and the stacked arrangement 604.

The vertical PIN heterojunction may include Ge or GeSn with barrier layers 604a, 604b that have a lower Sn-content. Contact holes can be made by a partial etch to make metal contacts to both the p-type layer 604a and the n-type layer 604b in the pad regions as denoted by ‘A’ and ‘C’. The bridge region (alternatively referred to as nanowire) may be denoted by ‘B’.

Electrons may be injected into the n-type layer 604b, and holes may be injected into the p-type layer 604a, both of which are subsequently confined in the intrinsic layer 604c (alternatively referred to as intrinsic active gain medium) in the nanowire, resulting in the emission of photons. The photons may be trapped between the two mirrors 610a, 610b, which cause stimulated emission of photons, and once threshold is reached, lasing may be achieved. To induce the tensile strain, portions of the tensile stressed metal pads 606a, 606b may be placed on the p-type layer 604a and the n-type layer 604b, respectively. In various embodiments, a thin layer of Al₂O₃ may also be inserted in between the GeSn stacked arrangement 604 and the SiO₂/AlN layer 608 (as shown in FIG. 5), so as to improve thermal management.

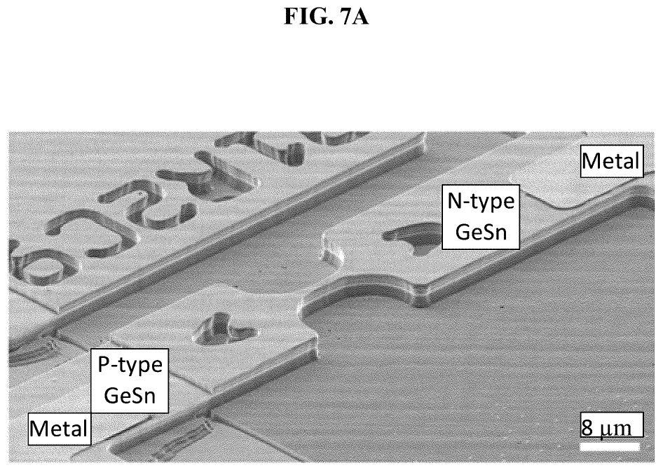

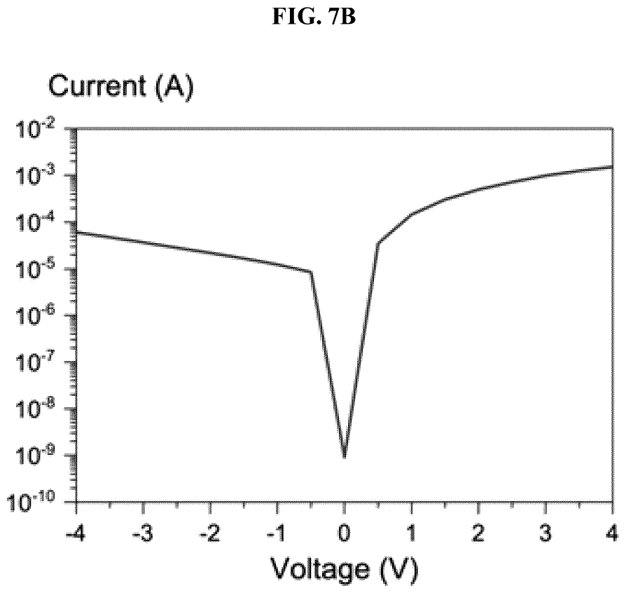

Electrically pumped light emitting diodes (LEDs) may be created by a sophisticated fabrication process. FIG. 7A shows a scanning electron microscope (SEM) image of a fabricated light emitting diode (LED) according to various embodiments. The fabricated LED may have a vertical PIN heterojunction. The overlying n-type and intrinsic GeSn layers in one of the pad regions may be partially etched to expose p-type GeSn layer. The metal contacts are then made on the n- and p-type GeSn layers for injection of electrons and holes, respectively. By measuring a current-voltage (I-V) curve of the fabricated device, it can be investigated whether the metals are contacted at n- and p-type GeSn layers. FIG. 7B shows a plot of current (in Amperes or A) as a function of voltage (in volts or V) illustrating the measured current-voltage (I-V) characteristics of the fabricated light emitting diode (LED) according to various embodiments. A rectified curve is shown due to the PIN substrate, confirming that the electrons and holes are injected through n- and p-type GeSn layers. By replacing the non-stressed metal pads in FIG. 7A with tensile stressed metal pads, it may become feasible to induce tensile strain in the bridge region, thereby enabling lasing.

### Design 2

Complementary Metal Oxide Semiconductor (CMOS)-compatible short- and mid-wave infrared emitters are highly coveted for the monolithic integration of silicon-based photonic and electronic integrated circuits to serve a myriad of applications in sensing and communications. In this regard, a group IV germanium-tin (GeSn) material epitaxially grown on silicon (Si) emerges as a promising platform to implement tunable infrared light emitters. Indeed, upon increasing the Sn content, the bandgap of GeSn narrows and becomes direct, making this material system suitable for developing an efficient silicon-compatible emitter. With this perspective, microbridge PIN GeSn LEDs with a small footprint of 1,520 μm² are demonstrated and their operation performance is investigated. The spectral analysis of the electroluminescence emission exhibits a peak at 2.31 μm and it red-shifts slightly as the driving current increases. It is found that the microbridge LED may operate at a dissipated power as low as 10.8 W at room temperature and just 3 W at 80 K. This demonstrated low operation power may be comparable to that reported for LEDs having a significantly larger footprint reaching 106 μm². The efficient thermal dissipation of various embodiments may help to reduce the heat-induced optical losses, thus enhancing light emission. Further performance improvements may be envisioned through thermal and optical simulations of the microbridge design. The use of GeSnOI substrate for developing a similar device may be expected to improve optical confinement for the realization of electrically driven GeSn lasers.

Reducing the footprint of CMOS-compatible optical interconnects is a key paradigm to address the relentless course toward the very dense integration of chips while maintaining high bandwidth and low power consumption. In fact, as future electronic chips require further device scaling, the associated miniaturization of metal interconnects suffers fundamental limits leading to high impedance and joule heating, which consequently limits the bandwidth. This stimulates a remarkable interest in merging silicon photonics with silicon-based integrated circuits for more efficient inter-chip and intra-chip communication, besides added multifunctional abilities such as on-chip optical modulation, spectroscopy, and sensing applications. However, the development of CMOS-compatible on-chip light sources remains a huge challenge owing to the lack of direct bandgap group IV semiconductors. Recently, GeSn has become a promising solution to overcome this limitation since GeSn becomes a direct bandgap material when sufficient Sn content is incorporated in Ge lattice. Indeed, the indirect-direct bandgap crossover occurs at a Sn content of around 8 atomic percent (at. %) in relaxed GeSn. Increasing the Sn content beyond this threshold improves the bandgap directness and lowers its energy. Photodetector devices made of chemical vapor deposition (CVD) and molecular beam epitaxy (MBE) grown layers and heterostructures have been demonstrated to operate at wavelengths up to 4.6 μm in the mid-infrared (MIR) spectral range. While optically pumped GeSn-based lasers have been reported by many researchers recently, experimental attempts to develop the electrically injected counterparts remain relatively scarce.

To achieve the dense integration of Si-based integrated circuits and silicon photonics, emitters with a small footprint and reduced power consumption are strongly desired. Several efforts have been expended toward this goal. While early GeSn LEDs feature low power consumption of 3.75 W, these devices have a remarkably large footprint area of around 106 μm². Other LED devices reported later on have two orders of magnitude smaller device sizes of around 31, 400 μm², but they require more than 4-fold higher power consumption. Various embodiments may relate to a GeSn microscale LED with a record-small footprint of around 1,520 μm² yet operating at a low dissipated power around 3 W at 80 K and around 10.8 W at room temperature. This may be realized through a cavity LED utilized in a microbridge structure.

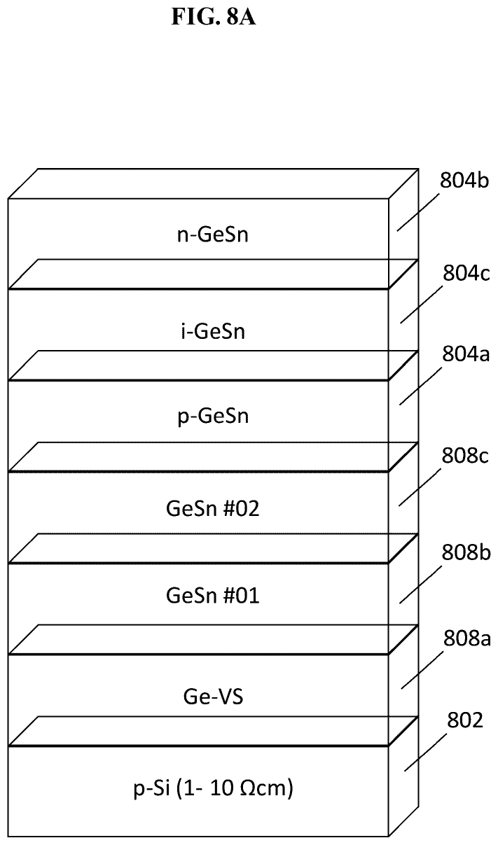

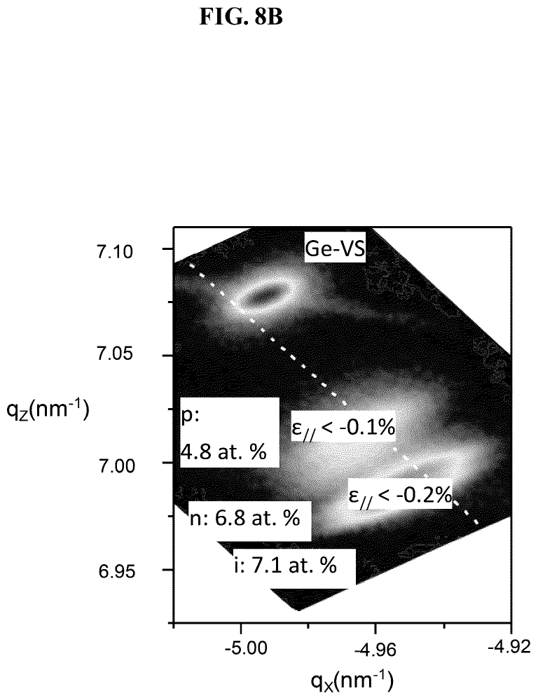

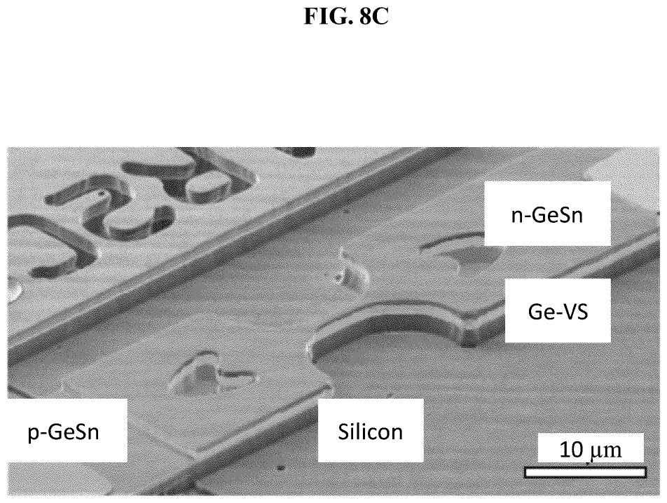

The GeSn LED samples may be grown using a low-pressure chemical vapor deposition (CVD) reactor following a multilayer growth to control lattice strain and Sn content. FIG. 8A shows a schematic of the formation of the stacked arrangement over the substrate according to various embodiments. The stacked arrangement may be formed using multilayer PIN GeSn growth over the silicon substrate 802. Starting from a 4-inch Si (100) wafer, a 2.67 μm thick Ge virtual substrate (VS) layer 808a may be grown using 10% monogermane (GeH₄) and a constant ultrapure hydrogen gas (H₂) flow implementing a two-temperature growth process at 450° C. and 600° C., followed by thermal cyclic annealing above 800° C. Two GeSn buffer layers 808b, 808c, with thicknesses of 140 nm and 208 nm, may be grown using GeH₄ and tin-tetrachloride (SnCl₄) precursors at initial molar fractions of (1.2× 10⁻²) and (9.1× 10⁻⁶), respectively. The first GeSn buffer layer 808b may be grown at 335° C., and the second GeSn buffer layer 808c may be grown at a lower temperature of 325° C., allowing more Sn to be substitutionally incorporated into the Ge lattice. Then, PIN GeSn layers 804a, 804c, 804b may be grown at thicknesses (temperatures) of 375 nm (335° C.), 830 nm (325° C.), and 330 nm (335° C.), respectively. The p- and n-type doping may be achieved using diborane (B₂H₆) and arsine (AsH₃) precursors, respectively. The p- and n-type active doping concentrations were estimated using capacitance-voltage (C-V) measurements to be at least 1×10¹⁹ cm⁻³ as the C-V setup measuring range was limited to 1×10¹⁹ cm⁻³.

FIG. 8B shows a plot of q_{z} (in per nanometer or nm⁻¹) as a function of qₓ (in per nanometer or nm⁻¹) illustrating the reciprocal space mapping (RSM) measurement around the asymmetrical (224) X-Ray diffraction (XRD) reflection peak indicating the tin (Sn) content and strain in the stacked arrangement according to various embodiments. According to the X-ray diffraction (XRD) reciprocal space mapping (RSM) measured around the asymmetrical (224) reflection peak, as shown in FIG. 8B, the Sn content is estimated to be 4.1 at. % (#1), 6 at. % (#2), 4.8 at. % (p-GeSn), 7.1 at. % (i-GeSn), 6.8 at. % (n-GeSn), respectively. It is also noticeable that the layers are remarkably relaxed with the highest bi-axial compressive strain below −0.2% in the i-GeSn layer 804c and the n-GeSn layer 804b.

FIG. 8C shows a scanning electron microscopy (SEM) image depicting the fabricated light emitting diode according to various embodiments. The fabricated device has a microbridge structure with a corner-cube cavity which was intended to enhance the light emission via optical confinement. A corner cube is used as the cavity in the device, as it has a relatively large minimum feature size of ˜5 μm that can be achieved through photolithography, as opposed to a Bragg reflector which may require electron beam lithography due to its much smaller minimum feature size of ˜100 nm. The microbridge structure with corner-cube mirrors may be patterned using photo-lithography, and the defined pattern may be transferred onto the GeSn layers 804a-c, 808a-c and the GeVS layer 808a using reactive ion etching (RIE) with chlorine (Cl₂) chemistry. A second photolithography step may be performed to anisotropically etch down to expose the p-doped GeSn layer 804a at one end portion of the device. Thus, the device may have exposed p-doped Sn area at one end portion of the device and exposed n-doped GeSn area on the opposing end portion of the device. The patterns for the metal contacts were then defined using photolithography at the p-doped GeSn area and the n-doped GeGn area. Subsequently, the p- and n-layers contacts including Cr/Au bilayer metal may be deposited using electron beam evaporation. First, 20 nm of Cr may be deposited, followed by 180 nm of Au deposition. The metal contact fabrication may be completed after a standard lift-off process.

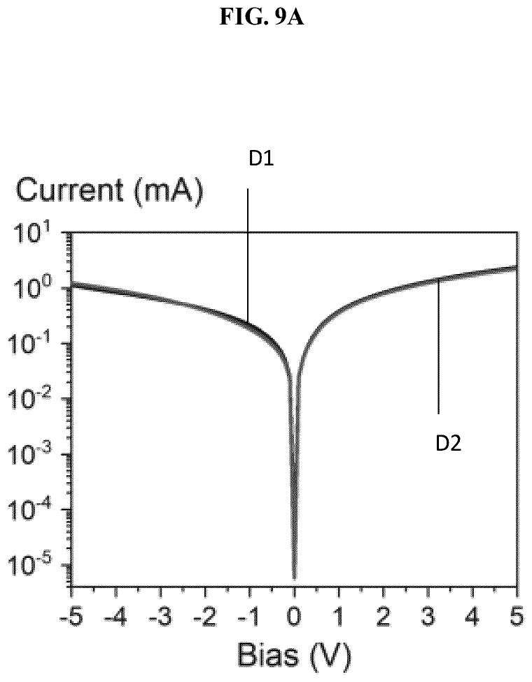

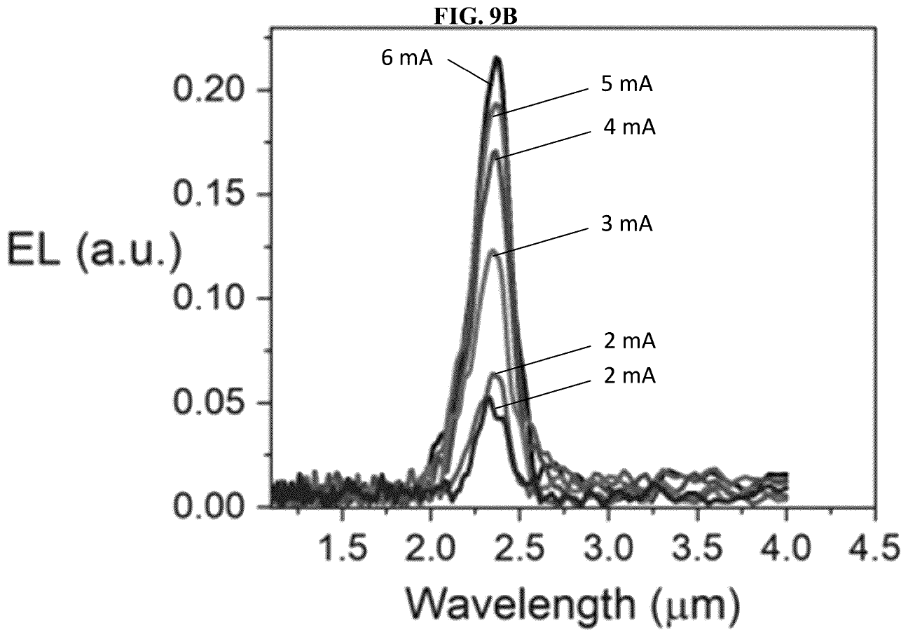

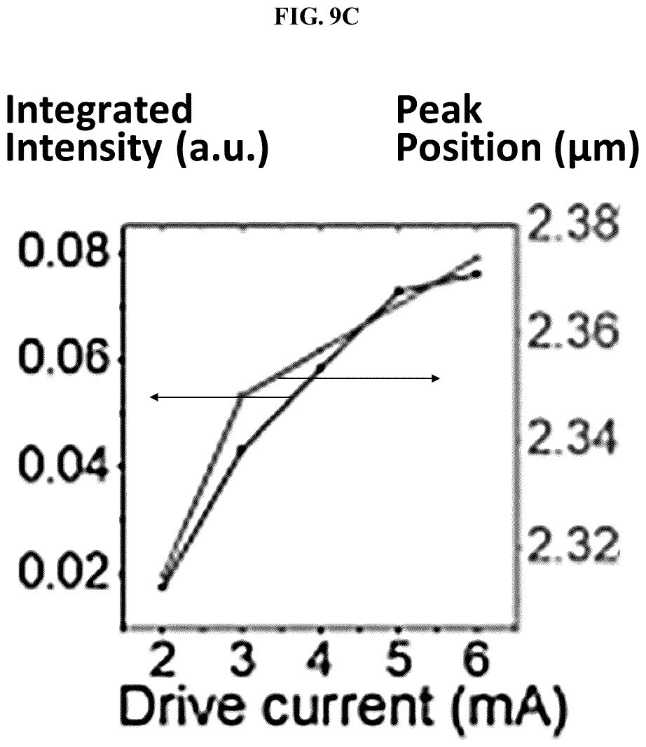

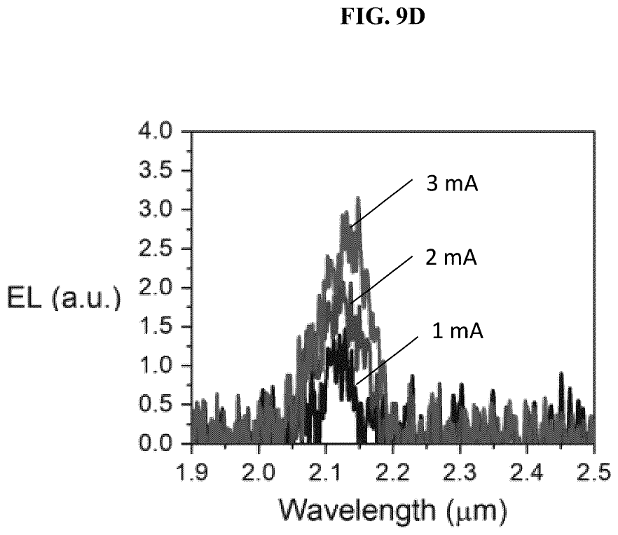

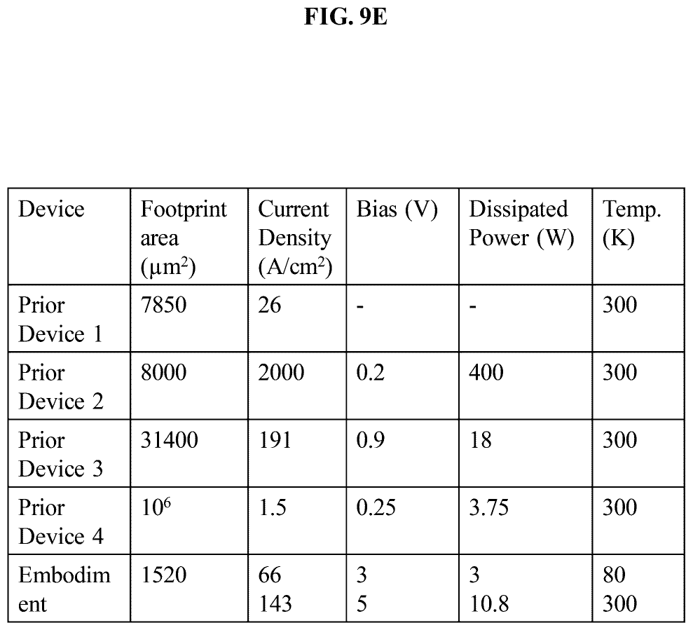

The microbridge device characterization started by measuring the I-V curves using a source meter unit over a wide bias range of up to 5 V in the forward and reverse biases as shown in FIG. 9A. FIG. 9A shows a plot of current (in milli-Amperes or mA) as a function of bias (in volts or V) illustrating the current-voltage (I-V) measurements for two light emitting diodes (D1 and D2) according to various embodiments with forward and reverse bias operations. The LED operating under forward bias may reach up to 2.16 mA at 5V, which corresponds to a power consumption as low as 10.8 W at such relatively high operation bias. The large current under the reversed bias, however, may indicate carrier leakage through the depletion region of the device possibly owing to various mechanisms including Shockley-Read-Hall (SRH), tunnel assisted, and diffusion leakages.

To measure and analyze the LED light emission, a Fourier transform infrared spectroscopy (FTIR) setup may be utilized to measure the spectral emission from the microbridge devices. The setup may include a Bruker Fourier Transform Infrared (FTIR) spectrometer, an indium antimonide (InSb) liquid nitrogen cooled photodetector (PD), a 40× reflective objective lens, and a translation stage. To amplify the InSb PD signal, the spectral emission was fed into a current preamplifier and a lock-in amplifier. The signal was re-entered into the FTIR for data processing. The lock-in technique requires the LED light to take the form of pulses either by mounting a mechanical chopper in the light path or by applying alternating current (AC) drive current to the LED. FIG. 9B shows a plot of electroluminescence EL (in arbitrary units or a.u.) as a function of wavelength (in micrometers or μm) illustrating the variation at different drive currents provided to the emission device at room temperature according to various embodiments. As shown, the electroluminescence (EL) was measured at driving currents from 2 mA to 6 mA with 1 mA stepwise. FIG. 9B shows two runs conducted at the same drive current of 2 mA. The two runs illustrate the repeatability of the results across multiple experiments. FIG. 9C shows a plot of integrated intensity (in arbitrary units or a.u.)/peak position (in micrometers or μm) as a function of drive current (in milli-Amperes or mA) illustrating the variation of integrated intensity and peak position with drive current provided to the emission device according to various embodiments. It is evident that the LED emission peak may be centered around 2.31 μm at the lowest drive current, and it may red-shift as the drive current increases. FIG. 9C also depicts that the integrated intensity of the EL emission initially increases linearly as the driving current increases, while it saturates at 6 V, indicating the drop in the LED emission efficiency possibly due to the heating effect.

The device was also characterized at a cryogenic temperature of 80 K, showing that a clear signal can be measured at a driving current as low as 1 mA. FIG. 9D shows a plot of electroluminescence EL (in arbitrary units or a.u.) as a function of wavelength (in micrometers or μm) illustrating the variation at different drive currents provided to the emission device at 80 Kelvins (K) according to various embodiments. It is also clear that the EL peak blue-shifts to 2.08 μm at 80 K compared to a significantly longer wavelength of 2.31 μm measured at room temperature, which may be attributed to the increased bandgap at a lower temperature.

FIG. 9E shows a table comparing the light emitting diode according to various embodiments with different prior devices. The table shows that the light emitting diode according to various embodiments have the lowest combined footprint (μm²) and power dissipation (I.V) at room temperature and at 80K.

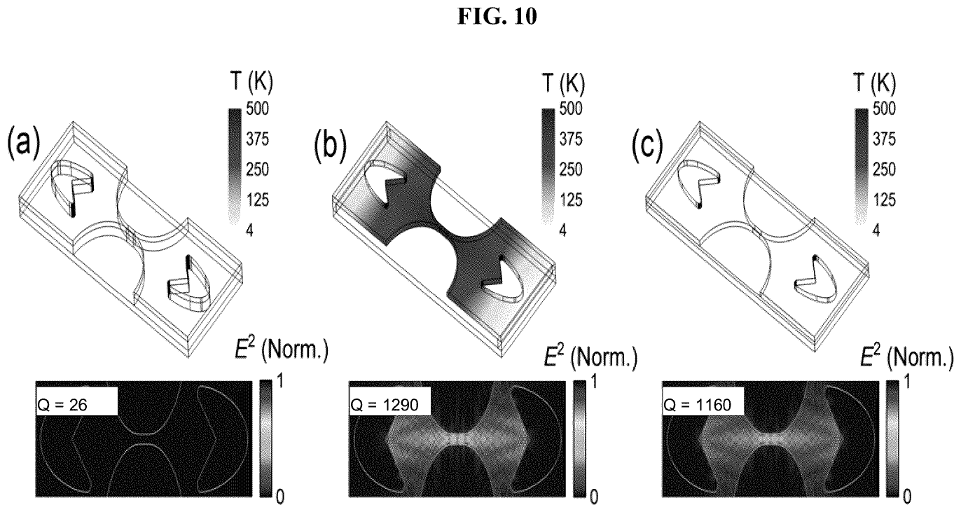

To investigate why the cavity effect is not achieved in the LEDs and provide a viable pathway towards achieving cavity effects and possibly lasing, thermal and optical simulations may be performed for the LED devices. FIG. 10 shows simulation of the thermal dissipation and optical confinement for the microbridge light emitting diodes according to various embodiments in three cases: (a) unreleased structure without under etch of the germanium virtual substrate (Ge VS) layer; (b) suspended structure with the germanium virtual substrate (Ge VS) layer under-etched; and (c) complete under etch of the germanium virtual substrate (Ge VS) layer to fully release the stacked arrangement, and arrangement on a silicon dioxide (SiO₂) substrate. FIG. 10 presents the simulated thermal (top) and optical fields (bottom) distributions calculated using a finite-element method (FEM) and finite-difference time-domain (FDTD), respectively, for three different LEDs. As highlighted above, (a) shows information relating to the device with no under etch, (b) shows information related to the device with the suspended structure, i.e. with Ge VS layer under etched except at the two end portions of the device (a gap under the bridge region between the first buffer layer and the substrate), and (c) shows information related to the device with the fully released stacked arrangement (the bridge region of the stacked arrangement is in contact with the substrate), which is made possible by utilizing a GeSn-on-insulator (GeSnOI) structure. In the thermal simulation, a heat source with a current density of 300 A/cm² was applied along the current path. The optical field distributions for the three structures were calculated at 2155 nm in the optical simulation. All the simulations were conducted at 4K. As shown in FIG. 10(a), the LED used in experiments as described above shows superior thermal conduction with a slightly increased temperature of ˜10 K but it has poor optical confinement with a very low quality (Q) factor of 26 due to the significant leakage of optical fields from the GeSn active layer to the Ge VS layer underneath. This explains why the cavity effect is not observed during the experiments. To address the limited optical confinement, a structure suspended in the air that can be fabricated by etching the Ge VS layer is designed and investigated. In stark contrast to poor optical confinement in the structure used in the experiments, a suspended structure as shown in FIG. 10(b) exhibits strong optical confinement with a high Q factor of 1290 because of the large refractive index difference between the GeSn active layer and air may prevent the leakage of optical fields. The temperature of an active area, however, may be increased significantly to ˜500K upon the current injection due to poor thermal dissipation in the suspended device geometry. As the increased temperature hinders optical emission in the active area due to heat-induced optical loss and also due to the reduced optical gain at an elevated temperature, an optimized structure may be envisioned to achieve both good optical confinement and thermal dissipation. FIG. 10(c) presents an optimized structure in which a GeSn active stacked arrangement or layer is laid down onto a SiO₂ substrate. It is worth mentioning that the optimized structure can be fabricated using the GeSnOI substrate. The optimized structure shows the simultaneous achievement of good heat dissipation with slightly increased temperature of ˜20 K and superior optical confinement with a high Q factor of 1160. Lasing may be feasible to achieve in the optimized structure.

The GeSn PIN homojunctions may be grown epitaxially on silicon wafers using step-graded buffer layers allowing the simultaneous control of the Sn incorporation, the lattice strain, and the interface abruptness, while confining the extended defects mainly below the active device layer. This growth protocol may ensure that the PIN homojunctions are of good crystalline quality despite having a Sn content significantly above the equilibrium content. The grown material was used to implement vertical GeSn microbridge LEDs. The operation performance of these LEDs was assessed using electrical and optical characterization. The emission peak was found to be around 2.31 μm at room temperature, which agrees with the estimated Sn content and strain revealed from the XRD RSM measurements. Low-temperature analysis showed an emission peak at a shorter wavelength around 2.08 μm. It was found that the microbridge LED has power dissipation as low as 3 W (at 80K) and 10.8 W (at room temperature), as well as a small footprint of 1,520 μm². To optimize the device design and layer structure, thermal and optical simulations were performed. The simulations indicate that the efficient thermal dissipation of the current design may help reduce the heat-induced optical losses, and may thus enhance light emission. According to thermal and optical simulations, various embodiments with the GeSnOI substrate may be promising for lasing.

Various embodiments may relate to an electrically pumped emission device. Various embodiments may operate using a direct bandgap configuration. Various embodiments may use a dual insulator material platform, thereby providing superior thermal management. Various embodiments may be free of misfit dislocation or may have fewer misfit dislocation compared to conventional devices and/or may have higher material quality, as various embodiments may use wafer bonding techniques and may have lower Sn content. In various embodiments, the stacked arrangement may be in contact with a solid layer instead of air, thereby providing more thermal conduction paths.

1. A light emission device comprising:
a substrate;
a stacked arrangement over the substrate, the stacked arrangement having a first pad region, a second pad region and a bridge region extending between the first pad region and the second pad region, the bridge region having a lateral width smaller than a lateral width of the first pad region, and smaller than a lateral width of the second pad region;
wherein at least a portion of the first pad region comprises a portion of a first doped layer;
wherein at least a portion of the second pad region comprises:
a further portion of the first doped layer;
a portion of a second doped layer; and
a portion of an intrinsic layer, the portion of the intrinsic layer between the further portion of the first doped layer and the portion of the second doped layer;
wherein the first doped layer comprises germanium (Ge) or germanium-tin (GeSn), and is of a first electrical conductivity type;
wherein the second doped layer comprises germanium (Ge) or germanium-tin (GeSn), and is of a second electrical conductivity type different from the first electrical conductivity type;
wherein the intrinsic layer comprises germanium-tin (GeSn), such that a percentage concentration of tin (Sn) of the intrinsic layer is higher than a percentage concentration of tin (Sn) of the first doped layer, and is higher than a percentage concentration of tin (Sn) of the second doped layer; and
wherein the light emission device further comprises:
a first tensile stressed metal pad in contact with the portion of the first doped layer; and
a second tensile stressed metal pad in contact with the portion of the second doped layer, such that first tensile-stressed metal pad and the second tensile-stressed metal pad cause a tensile strain in the bridge region.

2. The light emission device according to claim 1,
wherein the light emission device is configured to emit light upon application of a potential difference between the first tensile stressed metal pad and the second tensile stressed metal pad.

3. The light emission device according to claim 1, further comprising:
one or more buffer layers between the substrate and the stacked arrangement.

4. The light emission device according to claim 3,
wherein the one or more buffer layers comprise a first buffer layer comprising silicon dioxide (SiO₂) or aluminum nitride (AlN); and
wherein the one or more buffer layers further comprise a second buffer layer on the first buffer layer, the second buffer layer comprising aluminum oxide (Al₂O₃).

5. The light emission device according to claim 3,
wherein the one or more buffer layers comprise a virtual substrate layer comprising germanium;
wherein the one or more buffer layers further comprise a first buffer layer on the virtual substrate layer, the first buffer layer comprising germanium-tin (GeSn); and
wherein the one or more buffer layers further comprise a second buffer layer on the first buffer layer, the second buffer layer also comprising germanium-tin (GeSn).

6. The light emission device according to claim 5,
wherein the bridge region is over a gap between the first buffer layer and the substrate, or wherein the bridge region is in contact with the substrate.

7. The light emission device according to claim 5,
wherein a percentage concentration of tin (Sn) of the second buffer layer is higher than a percentage concentration of tin (Sn) of the first buffer layer.

8. The light emission device according to claim 1,
wherein the first tensile stressed metal pad comprises any suitable metal having a thermal expansion coefficient higher than a thermal expansion coefficient of the underlying first doped layer; and
wherein the second tensile stressed metal pad comprises any suitable metal having a thermal expansion coefficient higher than a thermal expansion coefficient of the underlying second doped layer.

9. The light emission device according to claim 1,
wherein the first pad region comprises a first reflector; and
wherein the second pad region comprises a second reflector.

10. The light emission device according to claim 9,
wherein the first reflector is a distributed Bragg reflector or a corner cube mirror; and
wherein the second reflector is a distributed Bragg reflector or a corner cube mirror.

11. The light emission device according to claim 1,
wherein the light emission device is a laser diode.

12. The light emission device according to claim 1,
wherein the light emission device is a light emitting diode.

13. A method of forming a light emission device, the method comprising:
forming a stacked arrangement over a substrate, the stacked arrangement having a first pad region, a second pad region and a bridge region extending between the first pad region and the second pad region, the bridge region having a lateral width smaller than a lateral width of the first pad region, and smaller than a lateral width of the second pad region;
wherein at least a portion of the first pad region comprises a portion of a first doped layer;
wherein at least a portion of the second pad region comprises:
a further portion of the first doped layer;
a portion of a second doped layer; and
a portion of an intrinsic layer, the portion of the intrinsic layer between the further portion of the first doped layer and the portion of the second doped layer;
wherein the first doped layer comprises germanium (Ge) or germanium-tin (GeSn), and is of a first electrical conductivity type;
wherein the second doped layer comprises germanium (Ge) or germanium-tin (GeSn), and is of a second electrical conductivity type different from the first electrical conductivity type;
wherein the intrinsic layer comprises germanium-tin (GeSn), such that a percentage concentration of tin (Sn) of the intrinsic layer is higher than a percentage concentration of tin (Sn) of the first doped layer, and is higher than a percentage concentration of tin (Sn) of the second doped layer; and
wherein forming the light emission device further comprises:
forming a first tensile stressed metal pad in contact with the portion of the first doped layer; and
forming a second tensile stressed metal pad in contact with the portion of the second doped layer, such that first tensile-stressed metal pad and the second tensile-stressed metal pad cause a tensile strain in the bridge region.

14. The method according to claim 13,
wherein the portion of the first pad region comprising the portion of the first doped layer is formed by etching an overlying portion of the second doped layer and an overlying portion of the intrinsic layer.

15. The method according to claim 13, further comprising:
forming one or more buffer layers between the substrate and the stacked arrangement.

16. The method according to claim 15,
wherein the one or more buffer layers comprise a first buffer layer comprising silicon dioxide (SiO₂) or aluminum nitride (AlN); and
wherein the one or more buffer layers further comprise a second buffer layer on the first buffer layer, the second buffer layer comprising aluminum oxide (Al₂O₃).

17. The method according to claim 15,
wherein the one or more buffer layers comprise a virtual substrate layer comprising germanium;
wherein the one or more buffer layers further comprise a first buffer layer on the virtual substrate layer, the first buffer layer comprising germanium-tin (GeSn); and
wherein the one or more buffer layers further comprise a second buffer layer on the first buffer layer, the second buffer layer also comprising germanium-tin (GeSn).

18. The method according to claim 17, further comprising:
under etching a portion of the virtual substrate layer between a portion of the first buffer layer and the substrate to form a gap under the bridge region of the stacked arrangement, or further under etching the portion of the first buffer layer and a portion of the second buffer layer under the bridge region to allow the bridge region to be in contact with the substrate.

19. The method according to claim 13, further comprising:
forming a first reflector in the first pad region; and
forming a second reflector in the second pad region.

20. The method according to claim 19,
wherein the first reflector is a distributed Bragg reflector or a corner cube mirror; and
wherein the second reflector is a distributed Bragg reflector or a corner cube mirror.
